(19) United States
(12) Patent Application Publication
(10) Pub. No.: US 2017/0330991 A1
(43) Pub. Date: Nov. 16, 2017

(54) METHOD OF HYDROGENATING SOLAR CELL AND THE DEVICE THEREOF

(71) Applicant: GINTECH ENERGY CORPORATION, Miaoli County (TW)

(72) Inventors: Chung-Chi LIAU, Miaoli County (TW); Chung-Chi LIU, Miaoli County (TW); Yan-Kai CHIOU, Miaoli County (TW); Kang-Cheng LIN, Miaoli County (TW); Kuei-Wu HUANG, Miaoli County (TW)

(21) Appl. No.: 15/201,517

(22) Filed: Jul. 4, 2016

(30) Foreign Application Priority Data
May 16, 2016 (TW) 105115074

(51) Int. Cl. H01L 31/18

(52) U.S. Cl. CPC H01L 31/186; H01L 31/18; H01L 31/1864

(57) ABSTRACT

The present invention provides a method of hydrogenating a solar cell and a device thereof. The device includes a chamber, a moving device, and a light-beam generator. The light-beam generated by the light-beam generator has a power density between 20 W/cm2 and 200 W/cm2 and a width between 1 mm and 156 mm. The light-beam scans a solar cell with a scanning speed between 50 mm/sec and 200 mm/sec to achieve hydrogenating the solar cell. Furthermore, the device includes a heating device used to heat the solar cell.

### RELATED APPLICATIONS

This application claims priority to Taiwanese Application Serial Number 105115074, filed May 16, 2016, which are herein incorporated by reference.

### BACKGROUND

### Field of the Invention

The present invention relates to a method of hydrogenating a solar cell and a device thereof.

### Description of Related Art

Solar cell is an environmentally friendly energy, which can directly transform solar energy into electrical energy. Existed solar cells, based on the main material, can be divided into silicon-based semiconductor solar cells, dye-sensitized solar cells, organic solar cells and other types of solar cells. Silicon-based semiconductor solar cell has the highest photovoltaic conversion efficiency and a low-cost advantage.

However, a silicon substrate of the silicon-based semiconductor solar cells usually has higher density of lattice defects and higher concentration of impurities. These impurities, such as oxygen, may further combine with the dopants, such as boron, doped into the silicon substrate to form positively-charged compounds, such as boron-oxygen compounds. In electricity-generating process of solar cells, these lattice defects or the positively-charged compounds will capture the electrons generated by light, which is called light-induced degradation (LID) phenomena. These phenomena will dramatically decrease photovoltaic conversion efficiency of solar cells, and the phenomena will be more seriously as increasing usage time. Therefore, a method for improving solar cells is needed to solve the aforementioned problems.

### SUMMARY

To solve the aforementioned problems, the present invention provides a method of hydrogenating a solar cell and a device thereof.

One aspect of the present invention provides a method of hydrogenating a solar cell. The method includes providing a solar cell and scanning the solar cell with a light-beam. The light-beam has a power density between 20 W/cm² and 200 W/cm² and a width between 1 mm and 156 mm. In addition, a scanning speed of the light-beam is between 50 mm/sec and 200 mm/sec.

According to some embodiments of the present invention, the light-beam has a wavelength between 450 nm and 1100 nm.

According to some embodiments of the present invention, the method of hydrogenating the solar cell further comprises heating the solar cell up to a temperature between room temperature and 400° C.

One aspect of the present invention provides a device of hydrogenating a solar cell. The device includes a chamber, a moving device and a light-beam generator. The moving device extends through the chamber and used for carrying a solar cell. The light-beam generator is disposed at an upper portion of the chamber and over the moving device.

According to some embodiments of the present invention, the device of hydrogenating the solar cell is connected to a fast firing furnace and a cell test system through the moving device.

According to some embodiments of the present invention, the device of hydrogenating the solar cell further comprises a heating device disposed underneath the moving device.

According to some embodiments of the present invention, the device of hydrogenating the solar cell further comprises a gas nozzle disposed near the light-beam generator, and an opening of the gas nozzle towards the solar cell underneath the light-beam generator.

According to some embodiments of the present invention, a light-beam generated by the light-beam generator has a power density between 20 W/cm² and 200 W/cm².

According to some embodiments of the present invention, a light-beam generated by the light-beam generator has a width between 1 mm and 156 mm.

According to some embodiments, the moving device has a moving speed between 50 mm/sec and 200 mm/sec.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a solar cell, in accordance with an embodiment of the present invention;

FIG. 2 illustrates a top view of a device of hydrogenating a solar cell, in accordance with an embodiment of the present invention;

FIG. 3 illustrates a side view of a device of hydrogenating a solar cell, in accordance with an embodiment of the present invention;

FIG. 4 illustrates a side view of a device of hydrogenating a solar cell, in accordance with an embodiment of the present invention; and

FIG. 5 illustrates a side view of a device of hydrogenating a solar cell, in accordance with an embodiment of the present invention.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Silicon (Si) substrates are usually used in solar cells, however, the Si substrates have high concentration of defects or impurities. Or, when P-type impurities, such as boron (B), are doped into the Si substrates, boron ions combine with oxygen ions of the Si substrates to form positively-charged BO⁺ compounds. During photovoltaic conversion processes of the polar cells, these defects, impurities or positively-charged BO⁺ compounds trap moving electrons so as to decrease photovoltaic conversion efficiency, which is called light-introduced degradation (LID).

The present invention provides a method of hydrogenating a solar cell and a device of hydrogenating a solar cell for improving the degree of LID of the solar cell so as to elevate the efficacy. The method is exciting hydrogen ions of the solar cell to a higher energy band by a light-beam so that the hydrogen ions can diffuse to the aforementioned defects, impurities or positively-charged BO⁺ compounds to neutralize the charge or passivate the defects. In this way, electrons will not be trapped by these positively-charged compounds or defects during the photovoltaic conversion process, and thus the photovoltaic conversion efficiency can be improved and the LID can be decreased.

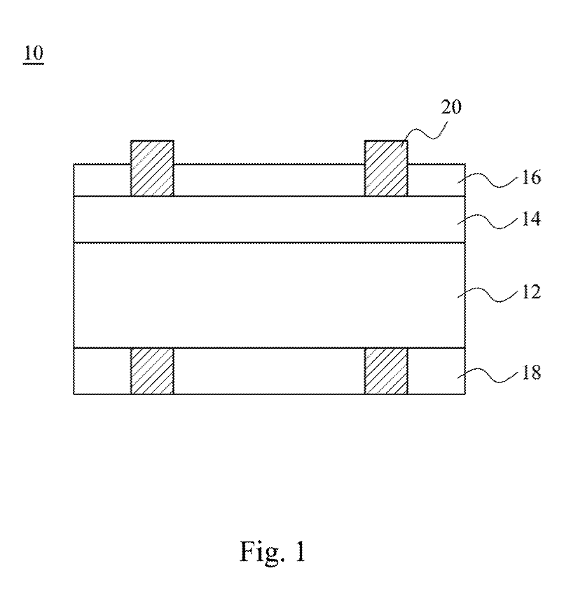

FIG. 1 illustrates a cross-sectional view of a solar cell, in accordance with some embodiments in the present invention. As shown in FIG. 1, in the embodiment, a solar cell 10 can be, but not limited to, P-type Si-substrate solar cell including a P-type Si-substrate 12, which is doped with P-type impurities such as boron (B), gallium (Ga), indium (In), a N-type semiconductor layer 14, an anti-reflection layer 16, an insulating layer 18 and a conductive layer 20. In some embodiments, the solar cell 10 further includes a hydrogen-ion-source layer, which can be formed by doping hydrogen ions into the insulating layer 18 over the P-type Si-substrate 12 through any doping ways such as ion implantation, plasma doping. It should be noted that the solar cell 10 may be various solar cells including various structures, which is not limited to what shown in FIG. 1.

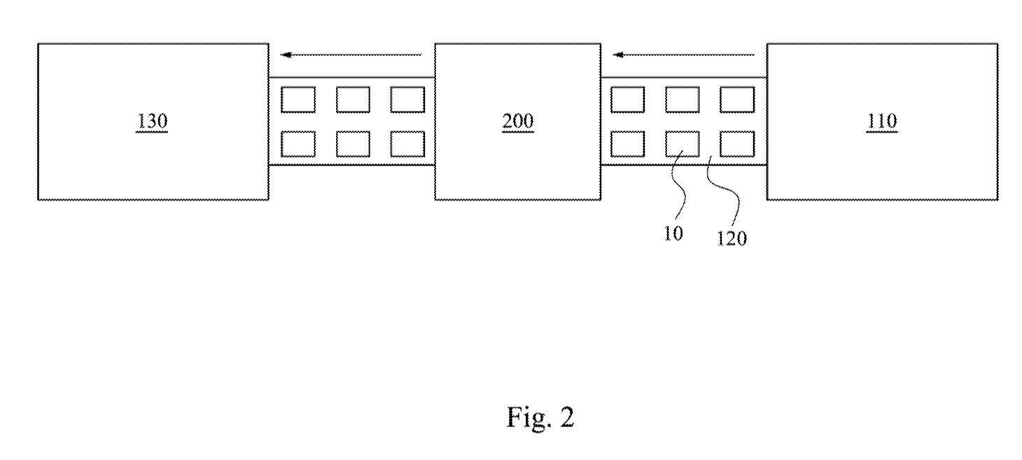

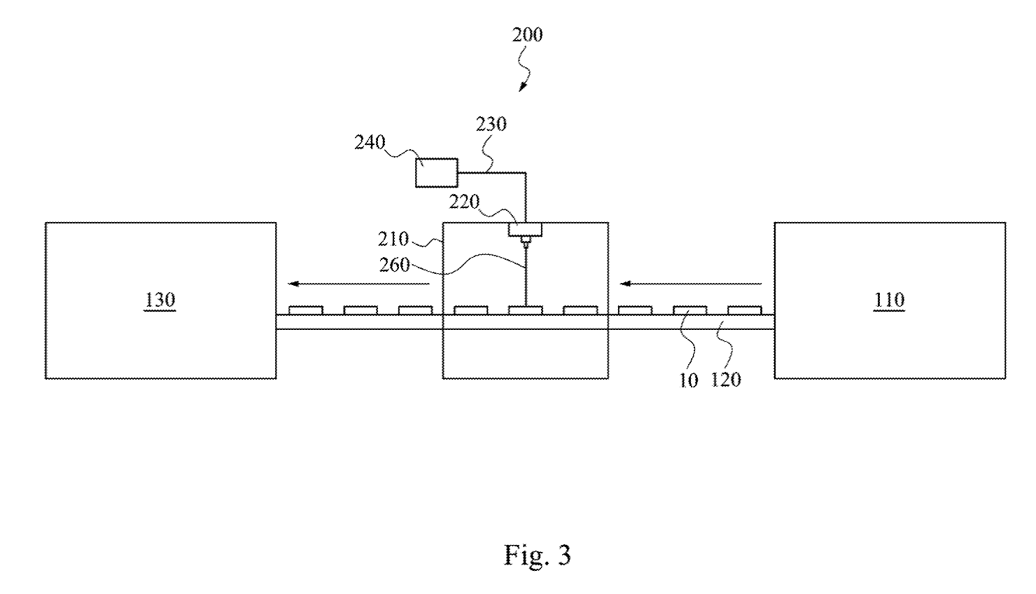

Please then refer to FIG. 2 and FIG. 3, which respectively illustrates a top-view and a side-view of a device 200 of hydrogenating a solar cell, in accordance with some embodiments in the present invention. As shown in FIG. 2, the device 200 of hydrogenating the solar cell is disposed between, but not limited to, a fast firing furnace (FFF) 110 and a cell test system (CTS) 130. Furthermore, the solar cell 10 just after sintered can undergo a hydrogenating process subsequently and be moved into the CTS 130 for efficiency test through a moving device 120. In some embodiments, the moving device 120 can be any moving carrier frequently used in industries such as, but not limited to, conveyer belt.

Please continue referring to FIG. 3. In some embodiments, the device 200 of hydrogenating the solar cell includes a chamber 210, a light-beam generator 220, a wire 230 and a light-beam control device 240. The light-beam control device 240 can control the power density, wavelength and width of a light-beam 260 generated by the light-beam generator 220 through the wire 230. It should be noted that the “width” used herein represents a width of the light-beam 260 in a direction parallel to the moving device 120. Furthermore, the moving device 120 has a fixed moving rate, which can generate a scanning speed of the light-beam 260 generated by the light-beam generator 220 in relative to the solar cell 10 over the moving device 120. The aforementioned power density, wavelength, width and scanning speed of the light-beam 260 will be described in details in the following. In other embodiments, the device of hydrogenating the solar cell does not include the chamber 210 but only be a light-beam generator, and can be disposed in other equipment for manufacturing solar cells instead of being restricted to space hindrance of the chamber.

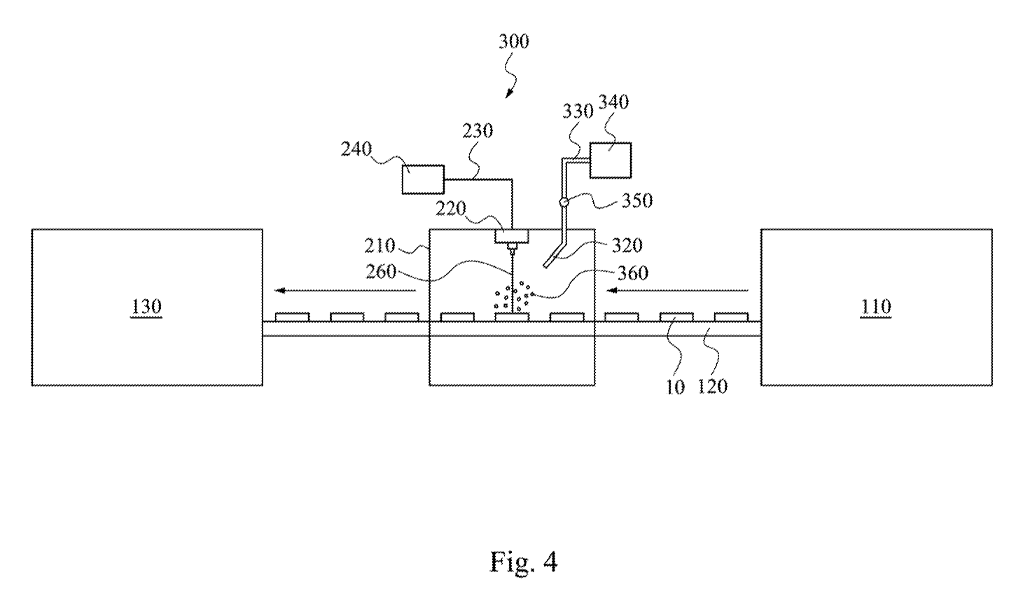

Please refer to FIG. 4, which illustrates a side view of another device 300 of hydrogenating a solar cell according to some embodiments of the present invention. As shown in FIG. 4, the device 300 of hydrogenating the solar cell includes a chamber 210, a light-beam generator 220, a wire 230, a light-beam control device 240, a gas nozzle 320, a gas flow rate control valve 350, a gas pipe 330 and a hydrogen tank 340. Different from the device 200 of hydrogenating the solar cell, the device 300 of hydrogenating the solar cell further includes a hydrogen-supplying device, providing high concentration of hydrogen at surfaces of the solar cell during the process of hydrogenating the solar cell to achieve the function of passivating the Si-substrate of the solar cell. To be more precise, the high-concentration hydrogen 360 can be delivered to the surfaces of the solar cell 10 through the gas pipe 320 and diffused into the inner parts of the solar cell under the light-beam so as to supplement the concentration of hydrogen of the inner parts of the solar cell and combine with the defects and the positively-charged compounds to achieve the passivation effect. In the embodiment, hydrogen is delivered to the upper surface of the solar cell 10 underneath the light-beam generator 220 with a tilted angle and through the gas pipe 330, the gas flow rate control valve 350 and the gas nozzle 320. In other embodiments, the gas nozzle can be disposed at any position in the device 300 of hydrogenating the solar cell and the hydrogen can be delivered to the solar cell 10 underneath the light-beam generator with any tilted angle. In other embodiments, the chamber 210 of the device 300 of hydrogenating the solar cell can be air-tight, and the gas nozzle is used to deliver high-concentration hydrogen into the chamber. In other embodiments, the gas nozzle can be a plasma nozzle which is a hydrogen ion plasma source, and the device of hydrogenating the solar cell may further include pulse generator connected to or underneath the solar cell. As such, hydrogen ions can be doped into the solar cell 10 in a way of plasma doping.

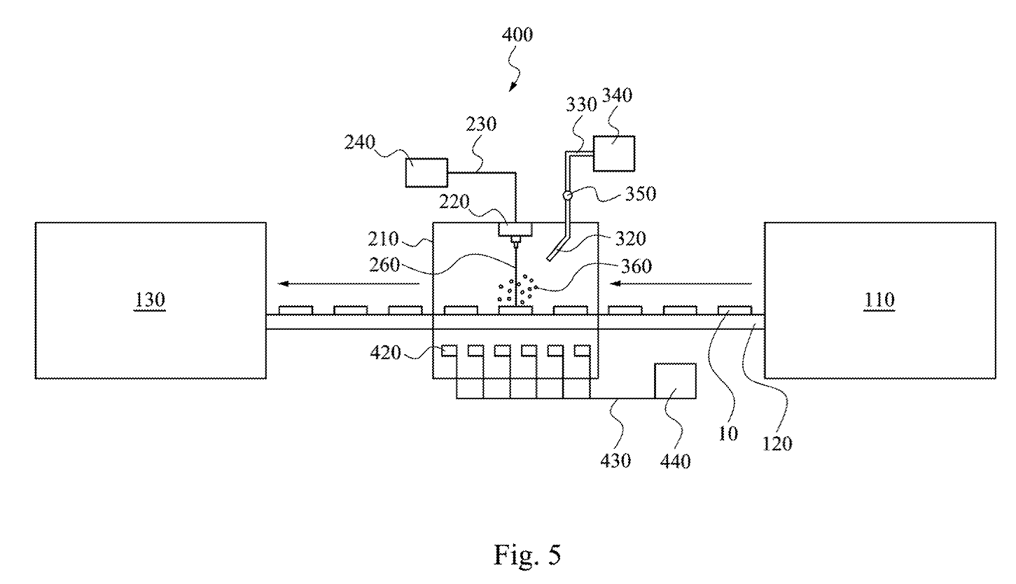

Please refer to FIG. 5, which illustrates a side view of another device 400 of hydrogenating a solar cell according to some embodiments of the present invention. As shown in FIG. 5, the device 400 of hydrogenating the solar cell includes a chamber 210, a light-beam generator 220, a wire 230, a light-beam control device 240, a gas nozzle 320, a gas flow rate control valve 350, a gas pipe 330, a hydrogen tank 340, a heating device 420, a wire 430 and a temperature controlling device 440. Different from the device 300 of hydrogenating the solar cell, the device 400 of hydrogenating the solar cell further includes a heating system to heat the solar cell during the process of hydrogenating the solar cell so as to increase the degree of hydrogenating the solar cell. In the embodiment, the heating device 420 is disposed underneath the moving device 120 and connected to the temperature controlling device 440 through the wire 430 to precisely control the heating temperature. In other embodiments, the chamber of the device of hydrogenating the solar cell is air-tight, and the heating device can be disposed at any position inside the device of hydrogenating the solar cell. As such, all places inside the device of hydrogenating the solar cell can reach a pre-determined temperature homogeneously.

The aforementioned light-beam 260 can be, but not limited to, laser or visible light. In some embodiments, the power density of the aforementioned light-beam 260 is between 0.01 W/cm² and 10000 W/cm², for example, 0.05 W/cm², 0.1 W/cm², 0.5 W/cm², 1 W/cm², 5 W/cm², 10 W/cm², 20 W/cm², 30 W/cm², 40 W/cm², 50 W/cm², 60 W/cm², 70 W/cm², 80 W/cm², 90 W/cm², 100 W/cm², 125 W/cm², 150 W/cm², 175 W/cm², 200 W/cm², 300 W/cm², 400 W/cm², 500 W/cm², 750 W/cm², 1000 W/cm², 2000 W/cm², 3000 W/cm², 4000 W/cm², 5000 W/cm², 6000 W/cm², 7000 W/cm², 8000 W/cm², and 9000 W/cm². In preferred embodiments, the power density of the light-beam is between 20 W/cm² and 200 W/cm².

In some embodiments, the wavelength of the aforementioned light-beam 260 is between 100 nm and 2000 nm, for example, 200 nm, 300 nm, 400 nm, 500 nm, 600 nm, 700 nm, 800 nm, 900 nm, 1000 nm, 1100 nm, 1200 nm, 1300 nm, 1400 nm, 1500 nm, 1600 nm, 1700 nm, 1800 nm, 1900 nm. In preferred embodiments, the wavelength of the light-beam is between 450 nm and 1100 nm.

In some embodiments, the width of the aforementioned light-beam 260 is between 0.1 mm and 300 mm, for example, 0.1 mm, 0.2 mm, 0.5 mm, 1 mm, 2 mm, 5 mm, 10 mm, 20 mm, 30 mm, 50 mm, 75 mm, 100 mm, 125 mm, 150 mm, 200 mm, 250 mm. In preferred embodiments, the width of the light-beam is between 1 mm and 156 mm.

In the embodiments, the scanning speed of the aforementioned light-beam 260 is between 10 mm/sec and 500 mm/sec, for example, 25 mm/sec, 50 mm/sec, 75 mm/sec, 100 mm/sec, 125 mm/sec, 150 mm/sec, 175 mm/sec, 200 mm/sec, 250 mm/sec, 300 mm/sec, 350 mm/sec, 400 mm/sec, 450 mm/sec. In preferred embodiments, the scanning speed of the light-beam is between 50 mm/sec and 200 mm/sec. It should be noted that the illuminating time of the solar cell 10 from the light-beam 260 can be precisely controlled by adjustably tuning the width and the scanning speed (i.e. the moving speed of the moving device) of the light-beam 260 to achieve the best hydrogenating effect. For example, the illuminating time of the solar cell 10 from the light-beam 260 is between 0.005 sec and 3 sec.

In some embodiments, the heating temperature of the aforementioned heating device 420 is between room temperature and 800° C., for example, 50° C., 100° C., 150° C., 200° C., 250° C., 300° C., 350° C., 400° C., 450° C., 500° C., 550° C.

In preferred embodiments, the heating temperature is between room temperature and 400° C.

In a specific embodiment, the solar cell 10 is hydrogenated by the device 200 of hydrogenating the solar cell for measuring the improvement of LID of the solar cell after the hydrogenating process. In the specific embodiment, the power density of the light-beam 260 is 0.1 W/cm², the wavelength of the light-beam 260 is between 400 nm and 700 nm, the width of the light-beam 260 is between 1 mm and 156 mm, and the scanning speed of the light-beam 260 is between 100 mm/sec and 150 mm/sec.

Then, the hydrogenated solar cell (treatment group) and non-hydrogenated solar cell (control group) are exposed to light-beam meanwhile and the accumulative exposure energy is 60 KWh/m², the photovoltaic conversion efficiency of the solar cells are measured and shown in the Table 1 below.

TABLE 1
photovoltaic conversion efficiency of the treatment group
and the control group.

| | Photovoltaic | Photovoltaic | Change of |
|---|---|---|---|
| | conversion | conversion | photovoltaic |
| | efficiency | efficiency | conversion |
| Group | (before test) | (after test) | efficiency |
| Control | 20.58% | 19.96% | −3.0% |
| group | | | |
| Treatment | 20.50% | 20.25% | −1.2% |
| group | | | |

As shown in Table 1, after the non-hydrogenated solar cell (control group) is exposed to light-beam and the accumulative exposure energy is 60 KWh/m², the photovoltaic conversion efficiency decreases from 20.58% (before test) to 19.96% (after test), which represents that the amount of LID is 3.0%. The photovoltaic conversion efficiency of the hydrogenated solar cell (control group) decreases from 20.50% (before test) to 20.25% (after test), which represents that the amount of LID is 1.2%. As a result, the method of hydrogenating the solar cell in the present invention can effectively improve the degree of light-induced degradation (LID).

As described in the aforementioned embodiments, the present invention has the following advantages. The device of hydrogenating the solar cell in the present invention can perform a hydrogenating process on a solar cell to improve the degree of light-induced degradation (LID). To be more precise, Using the device of hydrogenating the solar cell in the present invention to hydrogenate a solar cell, the amount of LID of the solar cell is less than 2% after the solar cell is exposed to a light-beam and the accumulative exposure energy is 60 KWh/m². Accordingly, the present invention provides a simple process for improving the decrease of the photovoltaic conversion efficiency of the solar cell in the following usage.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1-3. (canceled)

4. A device of hydrogenating a solar cell, comprising:
a chamber;
a moving device extending through the chamber and used for carrying a solar cell; and
a light-beam generator disposed at an upper portion of the chamber and over the moving device.

5. The device of claim 4, wherein the device of hydrogenating the solar cell is connected to a fast firing furnace and a cell test system through the moving device.

6. The device of claim 4, further comprising a heating device disposed underneath the moving device.

7. The device of claim 4, further comprising a gas nozzle disposed near the light-beam generator, and an opening of the gas nozzle towards the solar cell underneath the light-beam generator.

8. The device of claim 4, wherein a light-beam generated by the light-beam generator has a power density between 20 W/cm² and 200 W/cm².

9. The device of claim 4, wherein a light-beam generated by the light-beam generator has a width between 1 mm and 156 mm.

10. The device of claim 4, wherein the moving device has a moving speed between 50 mm/sec and 200 mm/sec.
